(19) United States
(12) Patent Application Publication
(10) Pub. No.: US 2007/0202612 A1
(43) Pub. Date: Aug. 30, 2007

(54) Plasma-Polymerisation Of Polycylic Compounds

(75) Inventors: Bjom Winter-Jensen, Victoria (AU); Keld West, Hellerup (DK)

Correspondence Address: FOLEY AND LARDNER LLP;SUITE 500, 3000 K STREET NW, WASHINGTON, DC, 20007, US

(73) Assignee: Forskiningscenter Riso

(21) Appl. No.: 10/594,133

(22) PCT Filed: Mar. 23, 2005
(86) PCT No.: PCT/DK05/00206

§ 371 Date: Apr. 3, 2007

Related U.S. Application Data
(60) Provisional application No. 60/556,482, filed on Mar. 26, 2004.

(30) Foreign Application Priority Data
Mar. 26, 2004 (DK) PA 2004 00491

(51) Int. Cl. H01L 21/00; B32B 9/04

(52) U.S. Cl. 438/1; 427/491; 977/900; 428/411.1

(57) ABSTRACT

The present invention relates to a method for the preparation of a layer of a plasma-polymerised material on the surface of a substrate, e.g. a substrate of a glass, an organosiloxane-based or polysiloxane-based material, silicon, fluoro-polymer (e.g. Teflon®), etc. The present invention also relates to novel objects and microstructured or micro-patterned devices, e.g. by lift-off techniques, in particular such objects and devices that have layers of electrically conducting materials providing a conductivity of at least 0.01 S/cm. A feature of the invention is the plasma-polymerization of a compound including at least one polycyclic compound, said polycyclic compound(s) comprising a non-aromatic heterocyclic ring fused to an aromatic or heteroaromatic ring or ring system. Examples of such compounds are 3,4-ethylenedioxythiophene (EDT) forming layers of poly(ethylenedioxythiophene) (PEDT), and piperonylamine, piperonyloyl chloride, safrole, 3,4-ethylenedioxypyrrole, 3,4-ethylenedioxy-N-methylpyrrole, and 3,4-methylenedioxythiophene.

### FIELD OF THE INVENTION

The present invention relates to a method for the preparation of a layer of a plasma-polymerised material on the surface of a substrate. The present invention also relates to novel objects and microstructured devices, in particular such objects and devices that have layers of electrically conducting materials.

### BACKGROUND OF THE INVENTION

Preparation of Electrically Conducting Surfaces Relies on the Ability to Deposit these Materials as thin, even coatings. A number of routes are available for this purpose, depending on the polymer and substrates in question. Most common are solution processing in the form of spin coating, solvent casting or printing. Conjugated polymer systems are, however, generally difficult to get into solution. It is often necessary to derivatise the polymer with soluble side chains or to dope the polymer with polyelectrolytes acting as solubilisers in order to be able to process these polymers. The choice of a conjugated polymer system for a given application may thus be restricted by the possibilities for finding a suitable compromise between functionality and processability.

Alternatively, a conjugated polymer can be deposited by in situ oxidative polymerisation directly at the surface. On conducting substrates, this can be achieved by electrochemical polymerisation, but this method is rarely suited for large-scale applications. Chemical oxidation on the other hand is more versatile and less restricted by the substrate. Chemical oxidation can be performed by coating the surface with a mixture of monomer and oxidant where the spontaneous reaction is suppressed in such a way that it will first occur after the mixture is spread onto the surface. Often such mixtures will have a limited pot life, and more freedom in the design of the coating process can be achieved if the monomer and oxidant are applied separately. One way to achieve this is to apply the oxidant by solvent coating and subsequently expose the coated surface to monomer vapour, a process that has been coined vapour phase polymerisation. Independent of the polymerisation route adhesion or bonding to the substrate has always caused problems due to the large difference in surface energy between the conjugated polymers and almost any substrate chosen.

U.S. Pat. No. 6,329,024 B1 discloses a method for depositing a coating comprising pulsed plasma-polymerisation of a macrocycle. Objects, e.g. contact lenses, coated with such a coating have improved properties with respect to non-fouling and wetting. Examples of macrocycles include benzo-crown ethers.

DE 101 38 696 A1 discloses a method involving the step of establishing a coating on the inner surface of a three-dimensional object by plasma-polymerization of, e.g., HMDSN, HMDSO, PMS, silane in N₂ or TiCl₄. There is not mentioning of plasma-polymerisation of compounds including at least one polycyclic compound, where said polycyclic compound(s) comprise(s) a non-aromatic heterocyclic ring fused to an aromatic or heteroaromatic ring or ring system.

US 2004/063336 A1 discloses precursor composition for chemical vapour deposition formation of low-k dielectric films, e.g. as interlayer dielectric material for making microelectronic device structures, comprising a mixture of aromatic compound(s) and an inert carrier medium.

EP 1 282 175 A2 discloses a conductive pattern material for forming fine wiring substrate that has pattern-forming layer which allows formation of hydrophilic/hydrophobic region bonded to support surface by imparting energy in image-wise manner.

WO 02/095497 A2 discloses a method of lift-off microstructuring deposition material on a substrate. The polymer materials are prepared by plasma-polymerisation of substituted benzenes or (halo)aliphatic compounds.

### SUMMARY OF THE INVENTION

The present invention provides highly relevant improvements of known technologies within the field of surface modification and microstructuring.

Thus, a first aspect of the present invention relates to a method for the preparation of a plasma-polymerised layer on at least a part of the surface of a substrate, said method comprising the steps of:

(a) providing the substrate;

(b) providing one or more compounds to become plasma-polymerised to form said layer;

(c) providing a gas plasma; and

(d) allowing said compound(s) to react within said gas plasma so as to form said plasma-polymerised layer on said substrate;

said one or more compounds including at least one polycyclic compound, said polycyclic compound(s) comprising a non-aromatic heterocyclic ring fused to an aromatic or heteroaromatic ring or ring system.

A second aspect of the present invention relates to an object comprising a substrate having a layer of one or more plasma-polymerised compounds on at least a part of the surface thereof, at least one of said compounds comprising a non-aromatic heterocyclic ring fused to an aromatic or heteroaromatic ring or ring system.

A third aspect of the present invention relates to an object comprising a substrate having a layer of a polymeric material on at least a part of the surface thereof, said polymeric material having pendant heteroaromatic rings or ring systems, and said polymeric material being covalently bonded to the substrate.

A fourth aspect of the present invention relates to a method for the preparation of a layer of an electrically conducting material on at least a part of the surface of a substrate, said method comprising the steps of:

(a) providing a substrate wherein at least a part of the surface is coated with a layer of a polymeric material including pendant heteroaromatic rings or ring systems and where said polymeric material is covalently bonded to the substrate;

(b) reacting said pendant heteroaromatic rings or ring systems with one or more second heteroaromatic compounds so as to form a layer of an electrically conducting material including the pendant heteroaromatic rings or ring systems and the second heteroaromatic compounds.

A fifth aspect of the present invention relates to an object comprising a substrate, wherein at least a part of the surface of said substrate is coated with a layer of a polymeric material and, integrated therewith, an electrically conducting material, said polymeric material being covalently bonded to the substrate and having pendant heteroaromatic rings or ring systems, and said electrically conducting material being the reacting product of the pendant heteroaromatic rings or ring systems of the polymeric material and one or more second heteroaromatic compounds.

A sixth aspect of the present invention relates to a process of lift-off microstructuring of a polymer on a substrate, said process comprising the steps of:

(a) providing the substrate having a sacrificial layer in a predetermined micro-pattern;

(b) depositing one or more layers of polymer material on the sacrificial layer/substrate; and

(c) dissolving/etching the underlying sacrificial layer (lift-off),

wherein the polymeric material is prepared as defined herein.

### BRIEF DESCRIPTION OF THE DRAWINGS

FIG. 1 illustrates the electrode configuration and the gas-flows in a plasma chamber.

FIG. 2 illustrates the voltage applied to the plasma chamber and the resulting pulsed plasma current.

FIG. 3a shows the infrared spectroscopy of 1,4-benzodioxane and plasma-polymerised 1,4-benzodioxane.

FIG. 3b shows the infrared spectroscopy of 1,3-benzodioxole and plasma-polymerised 1,3-benzodioxole.

FIG. 4 shows the infrared spectroscopy of 3,4-ethylenedioxythiophene and plasma-polymerised 3,4-ethylenedioxythiophene (PEDT).

FIG. 5 illustrates the procedure for photolithographic lift-off used for micro patterning of an electrically conducting polymer PEDT.

FIG. 6 shows the microscope picture of a micro pattern in poly(3,4-ethylenedioxythiophen); line width 2.5 μm.

FIG. 7 shows the molecular structures of piperonylamine, piperonyloyl chloride and safrole.

### DETAILED DESCRIPTION OF THE INVENTION

As mentioned above, an important aspect of the invention relates to a method for the preparation of a plasma-polymerised layer on at least a part of the surface of a substrate, said method comprising the steps of:

(a) providing the substrate;

(b) providing one or more compounds to become plasma-polymerised to form said layer;

(c) providing a gas plasma; and

(d) allowing said compound(s) to react within said gas plasma so as to form said plasma-polymerised layer on said substrate;

said one or more compounds including at least one polycyclic compound, said polycyclic compound(s) comprising a non-aromatic heterocyclic ring fused to an aromatic or heteroaromatic ring or ring system.

The method is particularly useful for providing substrates having on at least a part of the surface thereof a substantial density of aromatic or heteroaromatic ring or ring systems originating from the polycyclic compound(s), more particularly substrates having on at least a part of the surface thereof a layer of a polymeric material having pendant aromatic or heteroaromatic rings or ring systems. Such substrates are particularly useful for further reactions, such as reactions with second heterocyclic compounds, for the formation of layers of electrically conducting materials.

The Substrate

A wide range of substrates are suitable in the method of the invention, thus typically the solid substrate essentially consists of a material selected from polymers, e.g. polyolefins such as polyethylene (PE) and polypropylene (PP), and polystyrene (PS), and other thermoplastics such as fluoro-polymers (e.g. polytetrafluoroethylene (PTFE), tetrafluoroethylene-hexafluoropropylen copolymers (FEP), and polyvinyl-difluoride (PVDF)), polyamides (e.g. nylon 6 and nylon-11), polyvinylchloride (PVC), and rubbers; organosiloxane-based materials (e.g. silicone rubbers); glasses; silicon; paper; carbon fibres; ceramics; metals; etc.

Presently preferred materials are organosiloxane-based materials (e.g. silicone rubbers), glasses, silicon, and fluoro-polymers (e.g. polytetrafluoroethylene (PTFE)), of which silicon and glasses are particularly interesting in view of the particularly useful products for micro-structuring lift-off techniques (see further below). Conventional methods have shortcomings with respect to establishment of durable layers of polymeric materials on such substrates.

If the substrate is not supplied with sufficiently clean and ready-to-use surfaces, one or more initial cleaning treatments may be needed. Such cleaning treatments often depend on the substrate and are known in the art.

The substrate may be pre-coated or pre-treated in order to modify the properties thereof, e.g. the ability of the plasma-polymerised material to adhere to the substrate, or the hydrophobic or hydrophilic properties of the substrate as such. The pre-coating may be performed by plasma-polymerisation. In the case where the substrate is silicon or glass, it is preferred that the surface is pre-treated with a hydrogen plasma before the layer of material is provided onto the silicon in that occasional Si—OH groups are thereby converted to Si—H groups. This step can be performed as a pre-step to the step of providing the polymer layer. Also interesting is pre-treatment with argon so as to clean and possibly activates the surface prior to plasma-polymerisation (see the Examples section).

The substrate may be part of an object, or the substrate as such may constitute an object. Examples of very interesting objects for which the present invention is particularly applicable are micro-flow systems, “Lab on a chip”, flat screens, solar cells and membranes.

The One or More Compounds

The plasma-polymerised layer is formed from one or more compounds which include at least one polycyclic compound. The polycyclic compound comprises a non-aromatic heterocyclic ring fused to an aromatic or heteroaromatic ring or ring system.

The term “polycyclic” implies that the organic compound in question includes at least two closed rings, and that such rings are fused.

Within the present context, the term “non-aromatic heterocyclic ring” is intended to have it ordinary meaning, namely a carbocyclic ring where one or more of the carbon atoms have been replaced with heteroatoms, e.g. nitrogen (═N— or —NH—), sulphur (—S—), and/or oxygen (—O—) atoms. Preferably, the non-aromatic heterocyclic ring has 4-8 ring atoms.

In one currently preferred embodiment, the non-aromatic heterocyclic ring is of the type 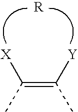
wherein X and Y independently are selected from the group consisting of ═C<(e.g. ═CH—), >C< (e.g. —CH₂—), —C(═O)—, —C(═N—)—, —O—, —S—, —N=and —NR^{N}— where R^{N} is selected from hydrogen and C₁₋₄-alkyl, with the proviso that at least one of X and Y is selected from —O—, —S—, —N=and —NR^{N}—.

It is found that the presence of one or two heteroatoms, X and Y, neighbouring the aromatic or heteroaromatic ring or ring system allows for plasma-polymerisation under moderate conditions. Thus, the plasma-polymerisation conditions can be adjusted so that any sensitive heteroaromatic rings or ring systems as well as groups as substitutents on the aromatic or heteroaromatic ring or ring system can remain substantially unaffected upon the plasma-polymerisation. The fact that the plasma-polymerisation proceed with a negative ΔPₚₗₐₛₘₐ (see the Examples section) indicates that the non-aromatic heterocyclic ring portion of the polycyclic compound reacts directly with the substrate surface.

In the above substructure, R is typically a biradical consisting of 1-4 groups/atoms, preferably 1-2 groups/atoms, independently selected from ═C<, >C<, —C(═O)—, —C(═N—)—, —O—, —S—, —N=and —N<. R may carry one or more substitutents, as it will be explained in the following.

The group/atom “═C<” designates a carbon atom having one double bond to a neighbouring ring atom and one single bond to another neighbouring ring atom and thereby carrying a substitutent, e.g. a hydrogen atom (i.e. ═CH—).

The group/atom “>C<” designates a carbon atom having (two) single bonds to neighbouring ring atoms thereby carrying two substitutents, e.g. one or two hydrogen atoms (i.e. —CH< or —CH₂—).

The group/atom “—C(═N—)—” designates a carbon atom having (two) single bonds to neighbouring ring atoms and a double bond to an exocyclic nitrogen atom. The nitrogen atom carries one substitutent, e.g. one hydrogen atom (i.e. —C(═NH)—).

The group/atom “—N<” designates a carbon atom having (two) single bonds to neighbouring ring atoms thereby carrying one substitutents, e.g. one hydrogen atom (i.e. —NH—).

Typical substitutents on the groups ═C< and >C< are hydrogen and those defined hereinbelow.

In one embodiment, the biradical R is selected from methylene, ethylene, and propylene.

In one embodiment, at least one of X and Y is —O—.

Illustrative examples of the non-aromatic heterocyclic ring are those selected from the group consisting of a 1,4-dioxane ring, a 1,3-dioxane ring, a morpholine ring, a tetrahydrofuran ring, a 1,3-dioxolane ring, a 1,3-oxazolidine ring, a pyrrolidine ring, a piperidine ring, a piperazine ring, a tetrahydro-2H-thiopyran ring, a 1,4-thioxane ring, a 1,3-thioxane ring, a tetrahydrothiophene ring, a 1,3-oxathiolane ring, a thiazolidine ring, a thiomorpholine ring, a 1,3-thiazinane ring, a 2,3-dihydrofuran ring, a 4,5-dihydro-1,3-oxazole ring, and a 4,5-dihydro-1,3-thiazole ring.

In a currently very interesting embodiment, both of X and Y are —O—, and R is selected from methylene and ethylene, i.e. the ring is a 1,4-dioxane ring or a 1,3-dioxolane ring.

The term “aromatic or heteroaromatic ring or ring system” is intended to cover aromatic carbocyclic rings and ring systems as well as aromatic heterocyclic rings and ring systems. Such rings and ring systems should—of course—include a ring to which the non-aromatic heterocyclic ring is fused.

Illustrative examples of the aromatic or heteroaromatic ring or ring system are those selected from the group consisting of a thiophene ring, a benzene ring, a pyrrole ring, a furan ring, a naphthalene ring, a quinoline ring, an iso-quinoline ring, a pyridine ring, a pyrimidine ring, a pyrazine ring, a pyridazine ring, a 1,2,4-triazine ring, an imidazole ring, an isoxazole ring, an oxazole ring, a pyrazole ring, a 1H-1,2,3-triazole ring, an isothiazole ring, a thiadiazole ring, a thiazole ring, a thianaphthene ring, an iso-thianaphthene ring, a quinone ring, an anthraquinone ring, a benzofurane ring, a benzothiophene, an indole ring, and a 1,4-naphthoquinone ring.

Particularly important are the embodiments wherein the aromatic or heteroaromatic ring or ring system comprises a heteroaromatic ring.

Particularly useful examples of such rings are thiophene, pyrrole, furan and pyridine.

The above definitions, of course, imply that the non-aromatic as well as the (hetero)aromatic part of the polycyclic compound may be substituted one or several times, typically 1-5 times, e.g. 1-3 times, with a wide range of substitutents. Illustrative examples of substitutents which may be present (possibly upon proper consideration of the plasma-polymerisation conditions) are hydroxy (which when present in an enol system may be represented in the tautomeric keto form), C₁₋₆-alkyl, C₁₋₆-alkoxy, oxo (which may be represented in the tautomeric enol form), carboxy, C₁₋₆-alkoxycarbonyl, C₁₋₆-alkylcarbonyl, formyl, aryl, aryloxy, aryloxy-carbonyl, arylcarbonyl, heteroaryl, amino, mono- and di(C₁₋₆-alkyl)amino; carbamoyl, mono- and di(C₁₋₆-alkyl)aminocarbonyl, amino-C₁₋₆-alkyl-aminocarbonyl, mono- and di(C₁₋₆-alkyl)-amino-C₁₋₆-alkyl-aminocarbonyl, C₁₋₆-alkylcarbonylamino, cyano, guanidino, carbamido, C₁₋₆-alkanoyloxy, sulphono, C₁₋₆-alkylsulphonyloxy, nitro, sulphanyl, dihalogen-C₁₋₄-alkyl, trihalogen-C₁₋₄-alkyl, halogen, where aryl and heteroaryl representing substitutents may be substituted 1-3 times with C₁₋₄-alkyl, C₁₋₄-alkoxy, nitro, cyano, amino or halogen. Preferred examples are hydroxy, C₁₋₆-alkyl, C₁₋₆-alkoxy, carboxy, C₁₋₆-alkoxycarbonyl, C₁₋₆-alkylcarbonyl, aryl, amino, mono- and di(C₁₋₆-alkyl)amino, and halogen, wherein aryl may be substituted 1-3 times with C₁₋₄-alkyl, C₁₋₄-alkoxy, nitro, cyano, amino or halogen.

A further group of possible “substitutents” are amino acids, peptides, oligonucleotide, oligonucleotide analogues and derivatives (e.g. PNA and LNA oligonucleotides), etc. Such “substitutents” can be linked to the polycyclic compound by means of traditional solution chemistry. Although such substitutents combined with the bicyclic structure may represent fairly “heavy” molecules, it is believed that heating thereof to a temperature below the decomposition temperature at reduced pressure (e.g. 5 Pa) so as to obtain a partial pressure of the molecule of about 0.5 Pa will render it possible to plasma-polymerise such compounds.

A class of currently particularly preferred polycyclic compounds include those that after the plasma polymerisation can participate in an oxidative polymerisation process with second heteroaromatic compounds leading to electrically conducting materials (see further below).

In a particular embodiment, the one or more compounds include at least one compound selected from the group consisting of 3,4-ethylenedioxythiophene, piperonylamine, piperonyloyl chloride, safrole, 3,4-ethylenedioxypyrrole, 3,4-ethylenedioxy-N-methylpyrrole, and 3,4-methylenedioxythiophene.

The one or more compounds may, beside the at least one polycyclic compound, generally include other compounds to be mixed and thereby co-polymerised with the polycyclic compound(s). Thus, other compounds can be used as the balance in the gas plasma (monomer gas) in order to modify the properties of the final plasma-polymerised layer. Such other compounds may be provided either by preparing a mixture of compounds to be applied simultaneous or by providing alternating amounts of different compound so as to form a virtual mixture in the plasma environment.

Illustrative examples of other compounds are ethylene, propylene, styrene, N-vinylpyrrolidone, vinylacetate, ethyleneglycolvinylether, diethyleneglycolvinylether, acrylic acid, methyl methacrylate, maleic acid, maleic anhydride, acrolein, acryloylchloride, acrylonitrile, allylalcohol, silanes (e.g. tetramethylsilane, hexamethyl-di-silane, tri-methylchlorosilane), tri-phosphites (e.g. tri-methyl-phosphite, triethyl-phosphite), vinylbornene, acid anhydrides (in particular carboxylic acid anhydrides), acid halides (in particular carboxylic acid halides) such as acid chlorides, acid bromides, acid fluorides, acid iodides, epoxides, aldehydes, carboxylic acids, thiols, toluene, xylene, benzaldehyde, chlorobenzene, di-chlorobenzene, tri-fluorobenzene, etc. In addition to the compounds above, the gas may also comprise gaseous constituents such as NH₃, N₂, N₂O, CO₂, etc.

Gas Plasma

The gas plasma can be established as described in the Examples section or as generally known from the literature, see, e.g., EP 96610018.2, EP 00901042.2 and EP 01980200.8

The plasma type advantageously used in the concept of the present invention is typically one generated by a multiple phase AC supply or a DC supply. It has been found that this type of plasma has a level of plasma power density which allows a substantial portion of the aromatic or heteroaromatic ring or ring structures to be preserved. It is particularly advantageous to utilise two- or three-phase AC plasma which offers the possibility of using a sufficiently low plasma power density, e.g. plasma power density of at the most 10 W/L, such as at the most 5 W/L.

Other types of generators of the plasma may also be applicable, e.g. RF and MF plasma and pulsed variants thereof, in particular for less energy sensitive functional groups of the one or more compounds.

The pressure in the reaction chamber will normally be in the range of 1-100 Pa, such as 2.5-50 Pa. The pressure in the reaction chamber is controlled by a vacuum pump, and a supply of an inert gas and the monomer gas. The inert gas is suitably a noble gas such as helium, argon, neon, krypton or a mixture thereof.

Hence, a plasma reaction chamber can be adapted in accordance with the instructions given herein with possible modification obvious for the person skilled in the art.

The plasma polymerisation process is normally conducted for a period of 10-1000 s, such as 20-500 s.

The plasma-polymerised layer can be provided on the substrate in a substantially uniform thickness, if desired. It is believed that the layer thickness of the material generally is in the range of 5-5000 nm, such as in the range of 10-1000 nm, typically 10-200 nm.

Due to the fact that it is desirable to allow the non-aromatic heterocyclic ring to be involved in the plasma-polymerisation, while at the same time allowing a substantial portion of the aromatic or heteroaromatic ring or ring system to be unaffected by the plasma-polymerisation reaction, the energy deposited in the gas plasma should be fairly low. In one preferred embodiment, the energy deposited in the gas plasma is less than 10 W/L, e.g. less than 5 W/L, and even more preferably less than 2.0 W/L, such as less than 1.5 W/L, or even less than 1.0 W/L, for example in the range of 0.010-2.0 W/L or 0.010-1.0 W/L.

It has proven particularly advantageous to utilise two- or three-phase AC plasma which offers the possibility of depositing a sufficiently low energy in the gas plasma, e.g. energy levels of at the most 15 W/L, such as at the most 10 W/L. Thus, in a preferred embodiment, said plasma being generated by a two or three phase AC supply, in particular where said two or three phase AC supply generates plasma having a plasma power density up to 10 W/L, preferably in the range of 0.010-2.0 W/L, in particular 0.010-1.0 W/L.

The expressions for various frequencies of a plasma have the following meanings: DC: 0 Hz, AC: 1 Hz to 10 kHz, RF: 13.45 MHz, and MF: about 2.6 GHz.

Plasma-Polymerisation of the One or More Compounds

The plasma-polymerisation of the one or more compounds yields substrates having a layer of the one or more plasma-polymerised compounds on at least a part of the surface thereof. In particular, the method provides substrates having a layer of a polymeric material on at least a part of the surface thereof, where said polymeric material having pendant aromatic or heteroaromatic rings or ring systems. As a particular feature, the polymeric material is covalently bonded to the substrate whereby the adhesive strength of the polymeric material to the substrate is excellent.

Also, the plasma-polymerisation technique renders it possible to provide a very thin layer of the polymeric material to the substrate, thus, preferably the layer has a thickness of in the range of 5-200 nm.

Furthermore, a substantial portion of the aromatic or heteroaromatic ring or ring system can be preserved under the plasma-polymerisation conditions. Thus, preferably at least 50% of the original number of aromatic or heteroaromatic ring or ring system can be found unaffected in the polymeric material. This facilitates the further functionalisation of the polymeric material.

Novel Objects

In view of the above, it is clear that the present invention also provides a range of novel objects comprising modified substrates, as well as object that may be known and prepared by alternative means.

Thus, a further aspect of the invention relates to an object comprising a substrate having a layer of one or more plasma-polymerised compounds on at least a part of the surface thereof, at least one of said compounds comprising a non-aromatic heterocyclic ring fused to an aromatic or heteroaromatic ring or ring system.

The one or more plasma-polymerised compounds are as defined above.

Thus, in a particular embodiment, the non-aromatic heterocyclic ring is of the type 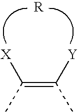
wherein X and Y independently are selected from the group consisting of ═C<, >C<, —C(═O)—, —C(═N—)—, —O—, —S—, —N=and —NR^{N}— where R^{N} is selected from hydrogen and C₁₋₄-alkyl, with the proviso that at least one of X and Y is selected from —O—, —S—, —N=and —NR^{N}—. In particular, at least one of X and Y is selected from —O—.

In a particularly interesting embodiment, the aromatic or heteroaromatic ring or ring system comprises a heteroaromatic ring. Suitable examples of corresponding compounds are 3,4-ethylenedioxythiophene, piperonylamine, piperonyloyl chloride, safrole, 3,4-ethylene-dioxypyrrole, 3,4-ethylenedioxy-N-methylpyrrole, and 3,4-methylenedioxythiophene.

It is believed that a particularly important novel group of object are those where the substrate is selected from organosiloxane-based materials, glasses, silicon and fluoro-polymers. Due to the limited reactivity of such substrates, it present invention provides hitherto unrealised possibilities with respect to surface modification of such substrates.

Due to the fact that it has hitherto been extremely difficult to covalently bond thin layers of polymeric materials to particular substrates and at the same time leaving behind pendant groups for further reactions, it is also believed that the present invention provides advantages in this respect.

Thus, the present invention also provides an object comprising a substrate having a layer of a polymeric material on at least a part of the surface thereof, said polymeric material having pendant heteroaromatic rings or ring systems, and said polymeric material being covalently bonded to the substrate.

In a particular embodiment thereof, the layer of the polymeric material has a thickness in the range of 5-200 nm.

In particular, and with regard to the above-mentioned, said polymeric material is typically a polymer of one or more compounds including at least one polycyclic compound, said polycyclic compound(s) comprising a non-aromatic heterocyclic ring fused to a heteroaromatic ring or ring system, wherein said heteroaromatic ring or ring system gives rise to the pendant heteroaromatic rings or ring systems of said layer of polymer material. More particularly, the polymeric material is a plasma-polymerised material.

In one variant thereof, the object comprises a substrate of an organosiloxane-based material, wherein at least a part of the surface of said substrate is coated with a layer of a non-organosiloxane-based polymeric material including pendant heteroaromatic rings or ring systems.

The term “non-organosiloxane-based” refers to the fact that the polymeric material does not include —Si—O— groups.

In another variant thereof, the object comprises a substrate of glass, wherein at least a part of the surface of said substrate is coated with a layer of a non-organosiloxane-based polymeric material including pendant heteroaromatic rings or ring systems.

In still another variant thereof, the object comprises a substrate of silicon, wherein at least a part of the surface of said substrate is coated with a layer of a polymeric material including pendant heteroaromatic rings or ring systems. Preferably, the layer is a non-organosiloxane-based polymeric material including pendant heteroaromatic rings or ring systems.

In a still further variant thereof, the object comprises a substrate of a fluoro-polymer, wherein at least a part of the surface of said substrate is coated with a layer of a polymeric material including pendant heteroaromatic rings or ring systems.

Various Uses of an Object with Pendant Aromatic or Heteroaromatic Rings or Ring Systems

The present invention allows for various uses based on the novel objects defined above:

a. New possibilities for plasma-polymerising highly ordered organic molecules, e.g. amino acids and peptides, where a polycyclic compound can be attached to the bio-molecule by normal wet-chemistry prior to the plasma-polymerisation. This leads to new possibilities in bio-compatible surfaces and surfaces with advanced bio-related properties, e.g. specific anti-body respond build into the coating.

b. Plasma polymerising monomers containing imidazole groups, especially for surfaces suitable for charge (proton) transfer purposes in membranes, where the preservation of the imidazole structure is essential for the efficiency of the membrane.

c. Preservation of the functionality of specific chemical groups (e.g. double bonds, acid chlorides or amines) in the monomer desired for binding selected groups or molecules to the plasma-polymerised layer (see also example 4, 5 and 6).

A further interesting use of the objects is the formation of a layer of an electrically conducting material involving the pendant heteroaromatic rings or ring systems. This will be explained in the following.

Preparation of a Layer of an Electrically Conducting Material

In view of the above-mentioned objects, a further aspect of the invention relates to a method for the preparation of a layer of an electrically conducting material on at least a part of the surface of a substrate, said method comprising the steps of:

(a) providing a substrate wherein at least a part of the surface is coated with a layer of a polymeric material including pendant heteroaromatic rings or ring systems and where said polymeric material is covalently bonded to the substrate;

(b) reacting said pendant heteroaromatic rings or ring systems with one or more second heteroaromatic compounds so as to form a layer of an electrically conducting material including the pendant heteroaromatic rings or ring systems and the second heteroaromatic compounds.

In a particular variant, step (b) includes an oxidative polymerisation reaction involving the pendant heteroaromatic rings or ring systems and the second heteroaromatic compounds. Oxidative polymerisation reactions leading to electrically conducting polymers represent a common polymerisation route for conducting polymers achieved from thiophene, pyrrole, furan and aniline or derivates of these monomers. An example is the reaction-scheme for polymerisation of 3,4-ethylenedioxythiophene using an iron(III)-salt (proposed by Bayer AG):

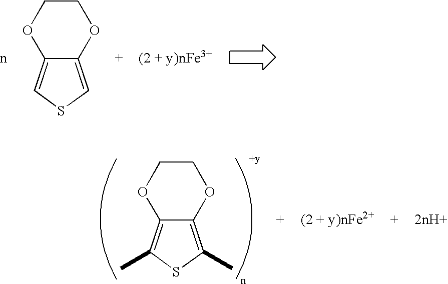

The value for “y” was later calculated to 0.25 (Aasmundtveit et al., Synth. Metals 1999, 101, 561-564). Many different oxidants can be used. Common are Fe(III)-salts, Cu(II)-salts and peroxy-disulfates. For each monomer great efforts have been used to find oxidants giving desirable properties as high conductivity, stability over time and smooth surface. For the polymerisation of 3,4-ethylenedioxythiophene, Fe(III)tosylate has shown remarkable properties.

In particular, the one or more second heterocyclic compounds include a compound selected from a thiophene compound, a pyrrole compound, a furan compound, and an aniline compound. Such compounds are known starting materials for electrically conducting materials, and by involving the pendant heteroaromatic rings or ring systems, an excellent adhesive strength to the substrate is obtained.

A particular example is where plasma-polymerised 3,4-ethylenedioxythiophene is used as covalent binding layer between a substrate an poly(3,4-ethylenedioxythiophene). This is possible because the thiophene-ring in the layer remains intact during the plasma-polymerisation and can participate as “co-monomer” in the following oxidative polymerisation of 3,4-ethylenedioxythiophene (see also example 2).

Also, it is possible to provide fairly thin layers of the electrically conducting material, e.g. the layer of the electrically conducting material may have a total thickness of in the range of 20-5000 nm.

In view of the above, the layer of the polymeric material is preferably a plasma-polymerised layer, e.g. prepared as described hereinabove.

The before-mentioned method—of course—gives rise to a further series of novel objects. Thus, a further aspect of the invention relates to an object comprising a substrate, wherein at least a part of the surface of said substrate is coated with a layer of a polymeric material and, integrated therewith, an electrically conducting material, said polymeric material being covalently bonded to the substrate and having pendant heteroaromatic rings or ring systems, and said electrically conducting material being the reacting product of the pendant heteroaromatic rings or ring systems of the polymeric material and one or more second heteroaromatic compounds.

The layer of the polymeric material and the electrically conducting material preferably have a total thickness of in the range of 25-5000 nm.

In view of the above-mentioned methods, the polymeric material is typically a polymer of one or more compounds including at least one polycyclic compound, said polycyclic compound comprising a non-aromatic heterocyclic ring fused to a heteroaromatic ring or ring system, wherein said heteroaromatic ring or ring system gives rise to the pendant heteroaromatic rings or ring systems of said layer of polymer material. More particularly, the polymeric material is a plasma-polymerised material, even more particularly a substrate and polymeric material prepared as described hereinabove.

In preferred embodiments, the conductivity of the electrically conducting layer is at least 0.01 S/cm.

Various Uses of an Object with a Layer of an Electrically Conducting Material

The present invention allows for various uses based on the novel objects defined above (for illustrative purposes described for the electrically conducting polymer PEDT:
1) Use connected with the function as binding layer between a substrate and a conducting polymer (PEDT) by plasma polymerisation of the EDT monomer followed by oxidative polymerisation of PEDT.
2) Binding PEDT to silicone rubber has various obvious applications in the electronic industry especially the cell-phone industry.
   a. For the short-circuit “dods” in keypads. Here the possibility to use conducting polymers represents a possible simplification of the production procedure, resulting in lower costs.
   b. For electromagnetic shielding of keypads and mobile phones. Normally electromagnetic shielding on flexible materials as silicon rubber is not possible because metal has been used. Obviously the different in modulus of silicone rubber and metals leads to problems concerning cracking of the metal layer and poor adhesion between the materials. By applying a 5 μm coating of PEDT shielding higher than 20 dB has been achieved.
   c. For printing conducting circuits (e.g. plastic electronics or organic light-emitting diodes (OLEDs)) directly on silicone rubber (and other polymers). This again represents a possible simplification of the production procedure, where printing technology (of PEDT on polymers) may replace the laborious and environmental questionable production of circuit-boards.
3) Binding PEDT to Teflon® and other “difficult” surfaces.
   a. Binding PEDT to fluoro-polymers for electromagnetic shielding of high-frequency cables and devices. Normally electromagnetic shielding on flexible materials as PEDT is difficult because metal has been the only serious conducting material used. Obviously the different in modulus of PEDT and metals leads to problems concerning cracking of the metal layer and poor adhesion between the materials.
   b. Binding PEDT to surfaces with high mechanical demands such as toys (e.g. LEGO® building blocks).
   c. Binding to glass and silicon (Solar cells). PEDT is a serious candidate for electrode material in polymer- and gratzel-solar cells. For the long-term stability of these products, a stabile bonding between the substrate—normally glass—and PEDT is essential.
4) Binding PEDT to surfaces used in contact with water and/or organic solvents. Conducting polymers tend to be very biocompatible and are therefore candidates for conductors where the conductor is in contact with a biological environment.
   a. Binding PEDT to surfaces in micro-flow devices. The PEDT is used as circuits or matrix for other devices (pH measurement, valve control, membrane pumps etc.).
   b. Binding PEDT to surfaces in (micro-flow) devices where the PEDT pattern is used to control the position of organic molecules and/or cells by applying different voltage (variation in time) to different parts of the PEDT pattern.
   c. PEDT used for circuits in active implants (e.g. drug-delivery systems for insulin).
      Microstructuring Using Lift-Off Techniques

A particular aspect of the invention relates to microstructuring using lift-off techniques. Designations and expressions in the present context, it is intended that the expression “microstructuring” has a similar meaning as the term “micropatterning”.

Thus, one aspect of the present invention relates to a process of lift-off microstructuring of a polymer on a substrate, said process comprising the steps of:

(a) providing the substrate having a sacrificial layer in a predetermined micro-pattern;

(b) depositing one or more layers of polymer material on the sacrificial layer/substrate; and

(c) dissolving/etching the underlying sacrificial layer (lift-off),

wherein the polymeric material is prepared as defined hereinabove.

The process takes advantage of conventional microstructuring techniques, e.g. the techniques disclosed in Canadian Patent No. 2448386.

In a particular variant, the process comprising the steps of:

(a) spinning a UV-sensitive photoresist on the substrate;

(b) masking the resist with a predetermined pattern and exposing the resist to UV light through the mask;

(c) developing the resist;

(d) depositing one or more layer(s) of polymer material on the resist/substrate; and

(e) dissolving the underlying UV-sensitive photoresist (lift-off).

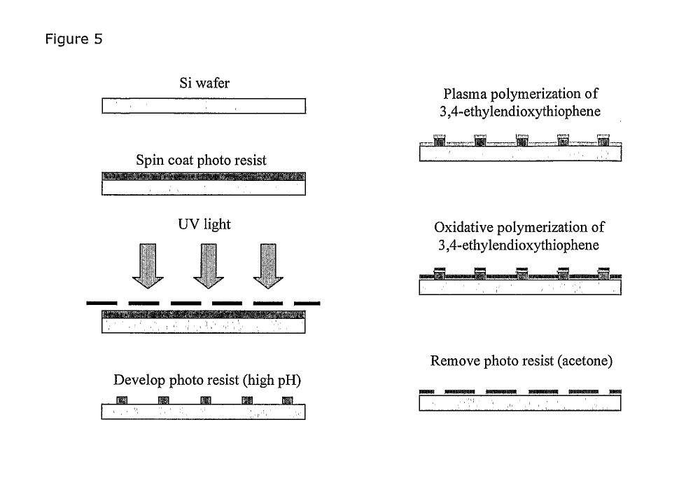

The process is illustrated in FIG. 5 wherein the layers (in step (d)) consists of a plasma-polymerised coating bonded to the substrate under the plasma-polymerisation and a layer of conducting polymer material polymerised by oxidative polymerisation and bonded to the plasma-polymerised coating during this oxidative polymerisation.

Preferably, the layer of the polymeric material includes pendant heteroaromatic rings or ring systems. In a particularly relevant embodiment hereof, the process comprises the further step of reacting said pendant heteroaromatic rings or ring systems with one or more second heteroaromatic compounds so as to form a layer of an electrically conducting material. The reaction typically includes an oxidative polymerisation reaction.

As mentioned above, it is possible to obtain a conductivity of the electrically conducting material of at least 0.01 S/cm.

The layer of the electrically conducting material typically has a total thickness of in the range of 20-400 nm.

Also, the layer of the polymeric material is typically a plasma-polymerised layer.

In one variant the sacrificial layer on the substrate comprises a mask with a complementary pattern of holes, said pattern corresponding to that of the microstructure to be deposited on the substrate, said holes being adapted to expose corresponding parts of the substrate and adapted to receive deposition material.

As it will be known from conventional microstructuring techniques, the process steps may be repeated twice or more times.

Various Uses of an Object with a Layer of an Electrically Conducting Material

The present invention allows for various uses based on the novel objects defined above:

Binding PEDT to a surface in combination with a (lithographic) lift-off procedure or a printing technique (ink-jet, off-set etc) to produce micro-pattern conducting polymers:
1) Binding PEDT to surfaces in micro-flow devices. The PEDT is used as circuits or matrix for other devices (pH measurement, valve control, membrane pumps etc.).
2) Binding PEDT to surfaces in (micro-flow) devices where the PEDT pattern is used to control the position of organic molecules and/or cells by applying different voltage (variation in time) to different parts of the PEDT pattern.
3) PEDT used for circuits in active implants (e.g. Drug-delivery systems for insulin).
4) Circuits and patterns for use in optical devices. Conducting polymers have the ability to change colour at different potentials. And thereby the possibility to work as a switching device.
5) Circuits and components (resistors, transistors etc.) in (polymer) electronic devices (e.g. Flat and flexible screens, radio-wave field transistors, plastic electronics, organic light-emitting diodes (OLEDs), and “smart” paper)

### EXAMPLES

Materials and Methods

The starting materials for the plasma polymerisation process were obtained from commercial sources (Sigma-Aldrich and Bayer AG) and used as received.

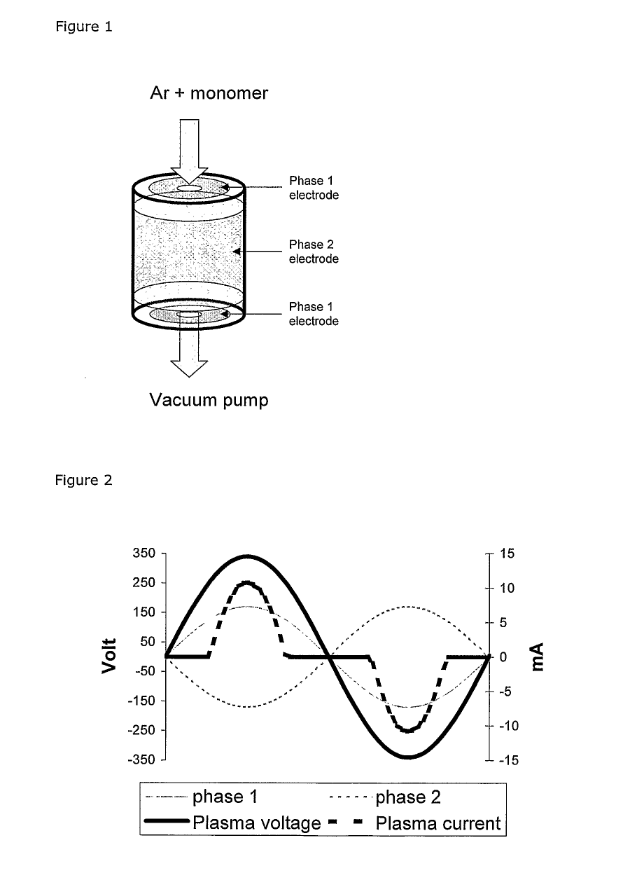

The plasma chamber used is a conventional cylindrical stainless steel vacuum chamber. The electrodes are of stainless steel and are isolated from the vacuum chamber. The electrode design is as showed in FIG. 1. The volume inside the electrodes—the actual plasma volume—is 11.5 L.

The flows of carrier gas (Ar) and monomer are regulated by flow-controllers and/or valves. A vacuum pump maintains the pressure in the chamber (working pressure 0.05 to 0.5 mbar) during the plasma treatment/polymerisation. The samples are pre-treated with Ar-plasma to improve adhesion between the substrate and the plasma-polymerised polymeric material.

The samples are placed in the centre of the chamber on floating potential (isolated from the electrodes). The plasma is powered from a 2-phase AC-supply. In the power-supply the 50 Hz AC from the grid (“phase 1”) is phase-shifted 180° (“phase 2”). The electrodes are powered with phase 1 and 2 as showed in FIG. 2.

The resulting voltage between the electrodes (the plasma voltage) is the sum of phase 1 and 2 (see FIG. 2).

To drive (ignite) the plasma, a voltage of around 250V is needed (depending on pressure and gas composition). The result is a (100 Hz) pulsing plasma current (se FIG. 2). The length of the “off” time is depending on the voltage supplied to the electrodes.

The energy deposited in the plasma is typically less than 1 W/L. Such low energy levels offer unique possibilities for plasma polymerisation.

A general parameter to describe a plasma polymerisation is the difference in pressure (ΔPₚₗₐₛₘₐ) in the vacuum chamber with and without plasma—and with all other parameters (gas and monomer flow and pump speed) constant.

If ΔPₚₗₐₛₘₐ is positive, the speed of fragmentation of molecules in the gas phase is higher than the speed of polymerisation on the surfaces. On the other hand; if ΔPₚₗₐₛₘₐ is negative the rate of polymerisation is higher than the fragmentation. A negative ΔPₚₗₐₛₘₐ indicates that the polymerisation is (mainly) due to reaction of intact monomer molecules on/with the surfaces.

A negative ΔPₚₗₐₛₘₐ can be achieved with monomers containing vinyl- or acrylic groups that can participate in a plasma-initiated radical polymerisation on the surfaces.

A negative ΔPₚₗₐₛₘₐ can—to our surprise—also be achieved with the new group of polycyclic compound monomers.

A positive ΔPₚₗₐₛₘₐ is typically achieved when monomers as alkenes or siloxanes are used, where fragmentation is necessarily to create active polymeriseable spices.

### Example 1—Plasma Polymerisation of 1,3-benzodioxole and 1,4-benzodioxane

1,4-Benzodioxane and 1,3-benzodioxole were plasma polymerised in the described low-power plasma system.

An argon flow of 5 sccm was used in all experiments. The plasma power was selected between 0.5 and 0.85 W/L and the partial pressure of monomer was 3.7 Pa for 1,4-benzodioxan and 4.2 Pa for 1,3-benzodioxole (without plasma).

For both monomers ΔPₚₗₐₛₘₐ were negative (−1 Pa and −1.6 Pa respectively) regardless of the plasma power.

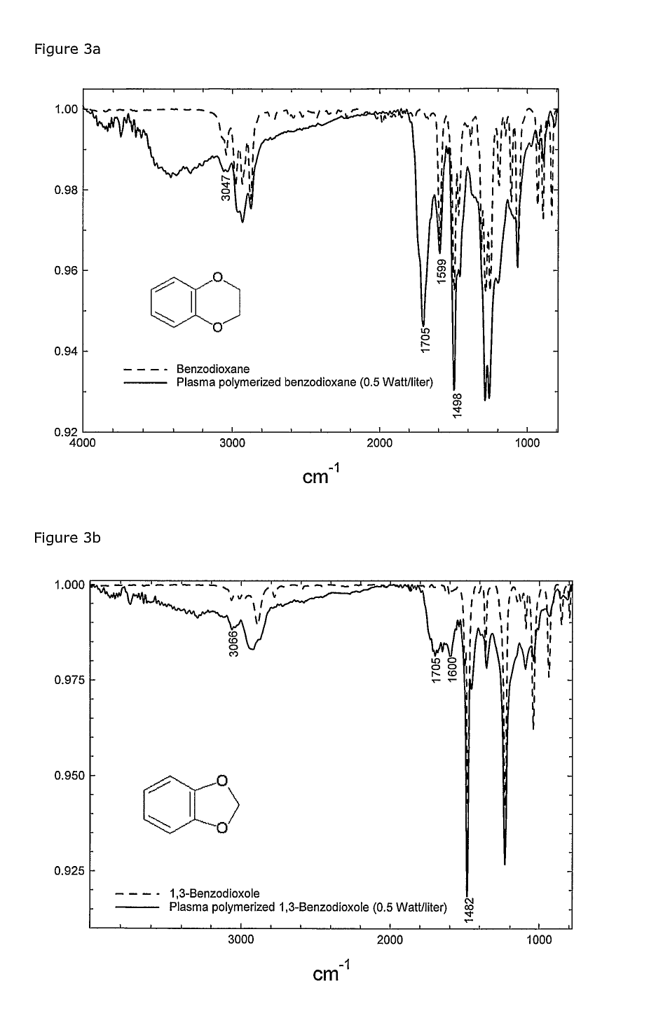

FIGS. 3a and 3b show FTIR spectra of the monomers and the plasma polymerised films.

In both cases, a preservation of the benzene ring (C═C bonds at ˜1490 cm⁻¹ and 1600 cm⁻¹ and ═C—H bonds ˜3045-3065 cm⁻¹) and appearance of carbonyl groups (C═O ˜1705 cm⁻¹) was observed. The carbonyl group can only have origin in the oxygen in the dioxane/dioxole rings and must be one of the resulting products of the polymerisation mechanism.

The negative ΔPₚₗₐₛₘₐ indicates that the monomers were able to polymerise on the surface (without pre-activation in the gas phase), this means that they must react with active species on the surface created by the plasma or produced in an earlier polymerisation step.

When 1,4-dioxane or morpholine were plasma polymerised under same conditions as described, ΔPₚₗₐₛₘₐ was positive (˜1.5 Pa). This means that the polymerisation mechanism seen with 1,4-benzodioxane and 1,3-benzodioxole was not in play, telling that a plain (cyclic)ether is not sufficient to initiate the found polymerisation mechanism.

### Example 2—Plasma polymerisation of 3,4-ethylenedioxythiophene Followed by Oxidative Polymerisation of poly-(3,4-ethylenedioxythiophene)

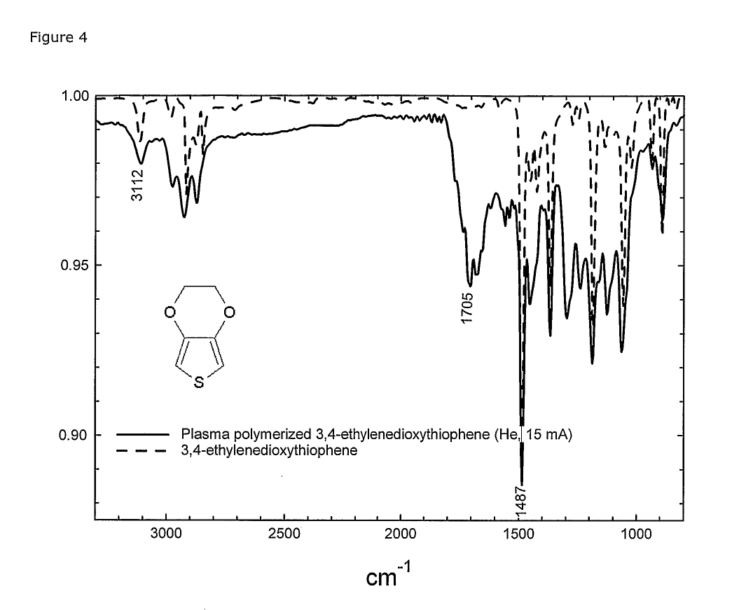

3,4-ethylenedioxythiophene (EDT) was plasma polymerised in the described low-power plasma system on polyethylene and PET foils as well as on glass slides. A large range of parameter settings has been tried (results not included). Under mild plasma conditions (e.g. power less than 0.5 W/L, He as preferred carrier-gas and total pressure 25 Pa) the plasma polymerised film (FTIR spectra, FIG. 4) showed significant signs that the thiophene ring structure was preserved, whereas the dioxane-ring was used for the polymerisation, leaving among others carbonyl groups as product.

The peak at 1705 shows the formed carbonyl group. The C═C bond in the thiophene-ring was seen both in the monomer and the plasma polymerised film at 1487 cm⁻¹. Of really great importance is the —C—H peak at 3112 cm⁻¹ showing that the α-H on the thiophene ring was preserved in the film. The presents of α-H opens the possibility to polymerise other thiophene-type monomers to the film by normal oxidative polymerisation (either chemically or electrochemically).

3,4-Ethylenedioxythiophene was oxidative polymerised using the EDT monomer (Baytron M) mixed with iron(III)tosylate solution (Baytron C) in a 1:6 ratio as recommended by Bayer AG. The mixture was coated on the plasma polymerised EDT films (on glass and PE) obtained as described above. When the solvent (butanol) evaporates, the oxidative polymerisation starts and conducting transparent blue films were formed. After wash in ethanol new FTIR spectra was made and no α-H was found indicating that the plasma polymerised film in fact takes part in the oxidative polymerisation—or in other words: The oxidative polymerised EDT was chemically bonded to the plasma polymerised EDT film.

The samples were stored in different solvents as water, ethanol, toluene, acetone and hexane for two weeks at room temperature without losing the binding to the sample. Argon plasma treated control samples without plasma polymerised EDT were also tested. Here the oxidative polymerised EDT easily peeled off in all solvents.

### Example 3—Plasma Polymerisation of 3,4-ethylenedioxythiophene as a Route to Micro-Patterning of Conducting poly-(3,4-ethylenedioxythiophene) Films by Lift-Off Technique

A silicium wafer was coated with photo resist and patterned by ordinary lithographic technique (FIG. 5), cf. R. Glang, Generation of patterns in thin films, in: Handbook of thin-film Technology, McGraw-Hill, New York, 1970, pp 7-10.

The wafer was then plasma coated with EDT in an equivalent way as described in Example 2, but with argon as carrier gas (argon flow 5 sccm, power 0.5 W/L, pressure 9.5 Pa, polymerisation time 90 sec.). Due to the harsh chemical conditions under the lift-off procedure, it was an advantage to pre-treat the wafer with H₂ plasma (according to patent EP 01931463.2)

After the plasma polymerisation, a mixture of EDT monomer and iron(III)tosylate in a 20% ethanol solution was spin coated on the wafer and polymerised (according to Example 2). The residual from the oxidative polymerisation (Fe(II) and tosylate) washed away with Millipore water.

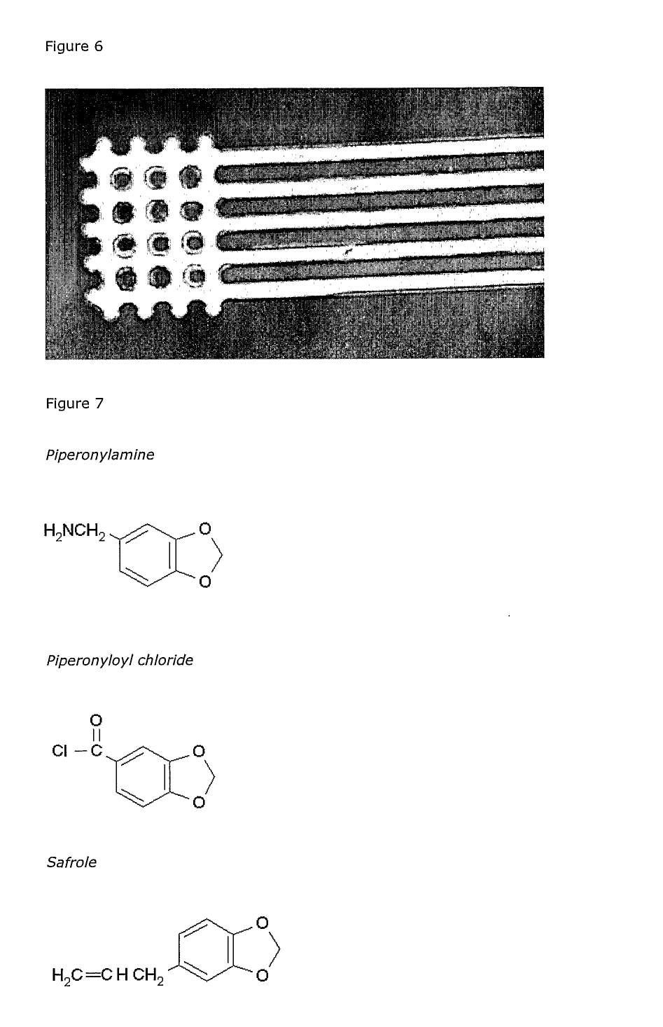

The photo resist was removed by acetone (20 seconds ultrasound) and thereby the conducting polymer was patterned. Line width down to 1.25 μm has been demonstrated at 100 nm thick films. FIG. 6 shows a test pattern with 2.5 μm line width.

For further details regarding micro-patterning of plasma polymerised films, see WO 02/095497 A2.

### Example 4—Plasma Polymerisation of Piperonylamine (FIG. 7)

Surfaces with a high density of specific chemical groups are commonly demanded for varies applications. One group of great interest is the amine group. Some of the obvious candidates among vinyl monomers (e.g. allylamine) have some build-in drawbacks. One of them is that the accentual amount at amine groups in the resulting film is surprisingly low. This might be due to the radical polymerisation mechanism which is involving the amine groups.

Piperonylamine or other amine containing monomers in the described new “family” of plasma polymerising monomers are good alternatives to the common amine monomers.

Piperonylamine was plasma polymerised in the described plasma chamber. Even though the vapor pressure of piperonylamine is quite low no heating was necessary.

The setting of the plasma parameters was as follows: 0.5 W/L (by 15 mA), total pressure 4.65 Pa, Argon flow 4 sccm and the partial pressure of piperonylamine 0.9 Pa. This gave a ΔPₚₗₐₛₘₐ of −0.3 Pa.

The polymerised films got a high content of amine groups. FTIR peaks for both primarily and secondary were found, but compared to plasma polymerised films from other amine monomers, the primarily amine peak was sharp and significant larger then the secondary amine peak.

### Example 5—Plasma Polymerisation of Piperonyloyl chloride (FIG. 7)

Another frequently demanded functionality is a surface that can bind amino terminated bio-molecules, e.g. DNA oligomers. The active chemical group can be acids, anhydrides, aldehydes or acid-chlorides (EP 1345705). The use of acid-chlorides has been demonstrated to be of special interest because of surprisingly good storage properties. Piperonyloyl chloride is a new monomer source for achieving surfaces with high content of acid chloride groups.

Piperonyloyl chloride was plasma polymerised in the described plasma chamber. The melting point of piperonyloyl chloride is 78-79° C., but already at a temperature around 50° C. the sublimation of piperonyloyl chloride was sufficient to maintain a usable monomer flow (at 10 Pa). The plasma parameters were set as follows: 0.3 W/L (by 10 mA), total pressure 7.5 Pa, argon flow 5 sccm, partial pressure of piperonyloyl chloride 2.5 Pa, resulting in a ΔPₚₗₐₛₘₐ of −0.9 Pa. The FTIR spectra of the polymerised films showed a significant peak around 1770 cm⁻¹, typical for the carbonyl (C═O) in benzoyl chloride.

### Example 6—Plasma polymerisation of Safrole (FIG. 7)

By plasma polymerisation of safrole, the strength of the described “new” group of plasma monomers was investigated.

Safrole was plasma polymerised in the described plasma chamber. The plasma parameters were as follows: 0.58 W/L (by 15 mA), total pressure 13.7 Pa, argon flow 5 sccm, partial pressure of safrole 8.7 Pa, resulting in a ΔPₚₗₐₛₘₐ of −6.4 Pa. This very large negative ΔPₚₗₐₛₘₐ compared to the ΔPₚₗₐₛₘₐ of 1,3-benzodioxole (−1.6 Pa) under similar conditions indicates that the vinyl group in safrole was indeed taking part in the polymerisation process.

The FTIR spectra of the polymerised safrole film—nevertheless—showed that the typical vinyl (C═C) peak at ˜1640 cm⁻¹ (from the monomer) was preserved in the plasma polymerised film and to some extend shifted to ˜1650 cm⁻¹. This means that at least a reasonable part of the vinyl groups from the monomer was present in the plasma-polymerised film. This observation was confirmed in tests were the film was reacted with heptafluorobutyryl chloride (HFBuCl) which selectively react with non-aromatic double bonds. By elementary analyses of the reacted film, serious amounts of fluorine were found (up to 8 atom %) underlining that vinyl groups indeed were present and reactive.

### Example 7—A Device for Moving and Immobilizing Cells with Voltage Fences

Studying living cells—or a particular cell—over longer periods of time, e.g. several days, is normally very difficult. Serious problems occur when the cells are moving around in the media (water) in an uncontrolled way, in that multiple-cell clusters are formed, etc. This makes the study very time-consuming and there is a risk that different cells are followed during the experiment.

Cells in water are mainly negatively charged. This means that they can be manipulated and immobilised by voltage—behaving as charged particles.

The use of metallic conductors in connection with living cells creates the risk that the cells are influenced by the metal due to dissolved metal-ions. On the other hand, it is known that many types of conducting polymers are good biocompatible materials. This makes is logic to use micro-patterned conducting polymers in micro bio-devices (“lab on a chip”, micro flow-cells etc.).

A pattern of conducting polymers was established in the bottom of well (20 μm deep) 4 mm in diameter by lift-off technique as described in example 3. The pattern was co-centric circles with a line-width of 10 μm (100 nm high) and a line spacing of 40 μm (in total 38 rings and a 10 μm dot in the centre). Each ring was connected to the outside of the device, thus, it was possible to address them individually.

The well was tested with polystyrene particles in water (2.5 μm average size) mimicking cells. The styrene is co-polymerised with 3% maleic anhydride and the polymer particles was therefore (like most cells) negativity charged in water. When a voltage of 2 V was applied between two rings second next to each other, say No. 1 (1 V negative, the water is “0”) and No. 3 (1 V positive) counted from the periphery of the well, it was possible to move the particles towards ring No. 3. When the voltage was shifted to ring No. 2 (neg.) and No. 4 (pos.) the particles was moved towards ring No. 4. By repeating this procedure it was possible to move the particles to the centre of the well. The whole manoeuvre took 20 min. (½ min. per ring).

This prototype device has proved that it was possible to move particles in water by the use of low voltage between conducting polymers micropatterned by lift-off technique. This opens up for applying the technique to bio-molecules like cells and proteins.

1. A method for the preparation of a plasma-polymerised layer on at least a part of the surface of a substrate, said method comprising the steps of:
(a) providing the substrate;
(b) providing one or more compounds to become plasma-polymerised to form said layer;
(c) providing a gas plasma; and
(d) allowing said compound(s) to react within said gas plasma so as to form said plasma-polymerised layer on said substrate;
said one or more compounds including at least one polycyclic compound, said polycyclic compound(s) comprising a non-aromatic heterocyclic ring fused to an aromatic or heteroaromatic ring or ring system.

2. (canceled)

3. The method according to claim 1, wherein the non-aromatic heterocyclic ring is of the type 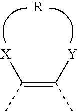
wherein X and Y independently are selected from the group consisting of ═C<, >C<, —C(═O)—, —C(═N—)—, —O—, —S—, —N=and —NR^{N}— where R^{N} is selected from hydrogen and C₁₋₄-alkyl, with the proviso that at least one of X and Y is selected from —O—, —S—, —N=and —NR^{N}—.

4. (canceled)

5. (canceled)

6. (canceled)

7. The method according to claim 1, wherein the one or more compounds include at least one compound selected from the group consisting of 3,4-ethylenedioxythiophene, piperonylamine, piperonyloyl chloride, safrole, 3,4-ethylenedioxypyrrole, 3,4-ethylenedioxy-N-methylpyrrole, and 3,4-methylenedioxythiophene.

8. (canceled)

9. The method according to claim 1, wherein the energy deposited in the gas plasma is less than 2.0 W/L.

10. The method according to claim 1, wherein the plasma-polymerised layer has a thickness of in the range of 5-200 nm.

11. An object comprising a substrate having a layer of one or more plasma-polymerised compounds on at least a part of the surface thereof, at least one of said compounds comprising a non-aromatic heterocyclic ring fused to an aromatic or heteroaromatic ring or ring system.

12. (canceled)

13. The object according to claim 11, wherein the non-aromatic heterocyclic ring is of the type 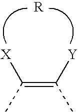
wherein X and Y independently are selected from the group consisting of ═C<, >C<, —C(═O)—, —C(═N—)—, —O—, —S—, —N=and —NR^{N}— where R^{N} is selected from hydrogen and C₁₋₄-alkyl, with the proviso that at least one of X and Y is selected from —, —S—, —N=and —NR^{N}—.

14. (canceled)

15. (canceled)

16. (canceled)

17. The object according to claim 11, wherein the one or more compounds include at least one compound selected from the group consisting of 3,4-ethylenedioxythiophene, piperonylamine, piperonyloyl chloride, safrole, 3,4-ethylenedioxypyrrole, 3,4-ethylenedioxy-N-methylpyrrole, and 3,4-methylenedioxythiophene.

18. (canceled)

19. The object according to claim 11, wherein the plasma-polymerised layer has a thickness of in the range of 5-200 nm.

20. An object comprising a substrate having a layer of a polymeric material on at least a part of the surface thereof, said polymeric material having pendant heteroaromatic rings or ring systems, and said polymeric material being covalently bonded to the substrate.

21. The object according to claim 20, wherein the layer of the polymeric material has a thickness of in the range of 5-200 nm.

22. The object according to claim 20, wherein said polymeric material is a polymer of one or more compounds including at least one polycyclic compound, said polycyclic compound(s) comprising a non-aromatic heterocyclic ring fused to a heteroaromatic ring or ring system, wherein said heteroaromatic ring or ring system gives rise to the pendant heteroaromatic rings or ring systems of said layer of polymer material.

23. The object according to claim 20, wherein said polymeric material is a plasma-polymerised material.

24. (canceled)

25. (canceled)

26. (canceled)

27. (canceled)

28. A method for the preparation of a layer of an electrically conducting material on at least a part of the surface of a substrate, said method comprising the steps of:
(a) providing a substrate wherein at least a part of the surface is coated with a layer of a polymeric material including pendant heteroaromatic rings or ring systems and where said polymeric material is covalently bonded to the substrate;
(b) reacting said pendant heteroaromatic rings or ring systems with one or more second heteroaromatic compounds so as to form a layer of an electrically conducting material including the pendant heteroaromatic rings or ring systems and the second heteroaromatic compounds.

29. (canceled)

30. (canceled)

31. (canceled)

32. The method according to claim 28, wherein the layer of the polymeric material is a plasma-polymerised layer.

33. The method according to claim 28, the wherein the substrate provided in step (a) is as defined as having a layer of a polymeric material on at least a part of the surface thereof, said polymeric material having pendant heteroaromatic rings or ring systems, and said polymeric material being covalently bonded to the substrate.

34. An object comprising a substrate, wherein, at least a part of the surface of said substrate is coated with a layer of a polymeric material and, integrated therewith, an electrically conducting material, said polymeric material being covalently bonded to the substrate and having pendant heteroaromatic rings or ring systems, and said electrically conducting material being the reacting product of the pendant heteroaromatic rings or ring systems of the polymeric material and one or more second heteroaromatic compounds.

35. (canceled)

36. (canceled)

37. The object according to claim 34, wherein said polymeric material is a plasma-polymerised material.

38. (canceled)

39. (canceled)

40. A process of lift-off microstructuring of a polymer on a substrate, said process comprising the steps of
(a) providing the substrate having a sacrificial layer in a predetermined micro-pattern;
(b) depositing one or more layers of polymer material on the sacrificial layer/substrate; and
(c) dissolving/etching the underlying sacrificial layer (lift-off),
wherein the polymeric material is prepared as defined in claim 1.

41. (canceled)

42. (canceled)

43. (canceled)

44. (canceled)

45. (canceled)

46. (canceled)

47. The process according to claim 40, wherein the layer of the polymeric material is a plasma-polymerised layer.

48. (canceled)

49. (canceled)
